(19) United States
(12) Patent Application Publication
(10) Pub. No.: US 2022/0289974 A1
(43) Pub. Date: Sep. 15, 2022

(54) THERMOPLASTIC COMPOSITION AND METALLIZED ARTICLES PREPARED THEREFROM

(71) Applicant: SHPP GLOBAL TECHNOLOGIES B.V., Bergen op Zoom (NL)

(72) Inventors: Weiyun JI, Shanghai (CN); Liang SHEN, Shanghai (CN); Mian DAI, Shanghai (CN); Chao LIU, Shanghai (CN); Lijuan WANG, Shanghai (CN)

(21) Appl. No.: 17/625,556

(22) PCT Filed: Jul. 17, 2020
(86) PCT No.: PCT/IB2020/056766

§ 371 Date: Jan. 7, 2022

Related U.S. Application Data
(60) Provisional application No. 62/875,553, filed on Jul. 18, 2019.

(51) Int. Cl. C08L 79/08

(52) U.S. Cl. CPC C08L 79/08; C08L 2205/03

(57) ABSTRACT

An article includes a composition including a high heat amorphous thermoplastic polymer having a glass transition temperature of greater than 180° C.; a poly(phenylene ether) oligomer; a flow promoter comprising a polyester, a poly (carbonate-ester), an aromatic poly ketone, poly(phenylene sulfide), or a combination thereof; and a mineral filler, wherein particular amounts of each component can be as defined herein. The article further includes a metal layer disposed on a surface of the composition. The articles of the present disclosure can be especially useful in consumer electronics applications.

### CROSS REFERENCE TO RELATED APPLICATIONS

This application claims priority to and the benefit of U.S. Provisional Application No. 62/875,553 filed on Jul. 18, 2019, which is incorporated by reference herein in its entirety.

### BACKGROUND

Thermoplastic compositions find use in a wide variety of applications, including in consumer electronics. Currently, many consumer electronics applications rely on metal parts. However, there is an ongoing interest in replacing metal parts with parts molded from polymers, as molded polymer articles can offer the advantages such as lower cost, high production speed, wide design latitude, lighter weight, and desirable mechanical properties.

For many applications, a metallic coating on the polymeric article is desired to further impart hardness, wear resistance, and metallic appearance and feel to the articles. Thus, there has been increasing interest in obtaining improved metal-to-polymer bonding. Accordingly, it would be particularly advantageous to provide a thermoplastic composition suitable for metallization, particularly for applications in consumer electronics.

### SUMMARY

An article comprises a composition comprising 30 to 94 weight percent of a high heat amorphous thermoplastic polymer having a glass transition temperature of greater than 180° C.; 0 to 6 weight percent of a poly(phenylene ether) oligomer; 1 to 15 weight percent of a flow promoter comprising a polyester, a poly(carbonate-ester), an aromatic polyketone, poly(phenylene sulfide), or a combination thereof; and 1 to 40 weight percent of a mineral filler; wherein weight percent of each component is based on the total weight of the composition; and a metal layer disposed on a surface of the composition.

A method of making the article comprises: melt-mixing the components of the compositions; molding the composition; and depositing a metal layer on a surface of the molded composition by electroless plating, electroplating, physical vapor deposition, or a combination thereof.

A composition comprises: 30 to 94 weight percent of a high heat amorphous thermoplastic polymer having a glass transition temperature of greater than 180° C.; 0 to 6 weight percent of a poly(phenylene ether); 1 to 15 weight percent of a flow promoter comprising a polyester, a poly(carbonate-ester), an aromatic polyketone, poly(phenylene sulfide), or a combination thereof; and 1 to 40 weight percent of a mineral filler; wherein weight percent of each component is based on the total weight of the composition.

The above described and other features are exemplified by the following detailed description.

### DETAILED DESCRIPTION

The present inventors have advantageously found that a particular thermoplastic composition is well-suited for providing metallized articles. The resulting compositions can have desirable mechanical properties including high modulus and stiffness, high heat resistance, good flowability, and good metallization capabilities.

Accordingly, an aspect of the present disclosure is a composition which can be particularly useful for providing metallized articles, for example for consumer electronics applications. The composition comprises a high heat amorphous thermoplastic polymer having a glass transition temperature of greater than 180° C. Glass transition temperature can be determined by methods that are generally known, for example by differential scanning calorimetry (DSC). In an aspect, the high heat amorphous thermoplastic polymer can be a polyimide, a polyetherimide, a polysulfone (PSU), a poly(phenylsulfone) (PPSU), a poly(ethersulfone) (PES), or the like, or a combination thereof.

In an aspect, the high heat thermoplastic polymer can be a polyimide, and in particular, a polyetherimide. Polyimides comprise more than 1, for example 5 to 1000, or 5 to 500, or 10 to 100, structural units of formula (1)

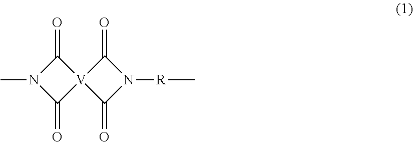

wherein each V is the same or different, and is a substituted or unsubstituted tetravalent C₄₋₄₀ hydrocarbon group, for example a substituted or unsubstituted C₆₋₂₀ aromatic hydrocarbon group, a substituted or unsubstituted, straight or branched chain, saturated or unsaturated C₂₋₂₀ aliphatic group, or a substituted or unsubstituted C₄₋₈ cycloaliphatic group, in particular a substituted or unsubstituted C₆₋₂₀ aromatic hydrocarbon group. Exemplary aromatic hydrocarbon groups include any of those of the formulas

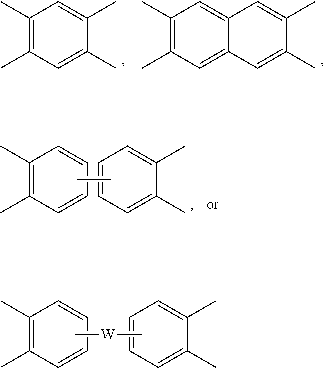

wherein W is —O—, —S—, —C(O)—, —SO₂—, —SO—, a C₁₋₁₈ hydrocarbon moiety that can be cyclic, acyclic, aromatic, or non-aromatic, —P(R^{a})(═O)— wherein R^{a} is a C₁₋₈ alkyl or C₆₋₁₂ aryl, —C_{y}H_{2y}— wherein y is an integer from 1 to 5 or a halogenated derivative thereof (which includes perfluoroalkylene groups), or a group of the formula —O—Z—O— as described in formula (3) below.

Each R in formula (1) is the same or different, and is a substituted or unsubstituted divalent organic group, such as a C₆₋₂₀ aromatic hydrocarbon group or a halogenated derivative thereof, a straight or branched chain C₂₋₂₀ alkylene group or a halogenated derivative thereof, a C₃₋₈ cycloalkylene group or halogenated derivative thereof, in particular a divalent group of formulas (2)

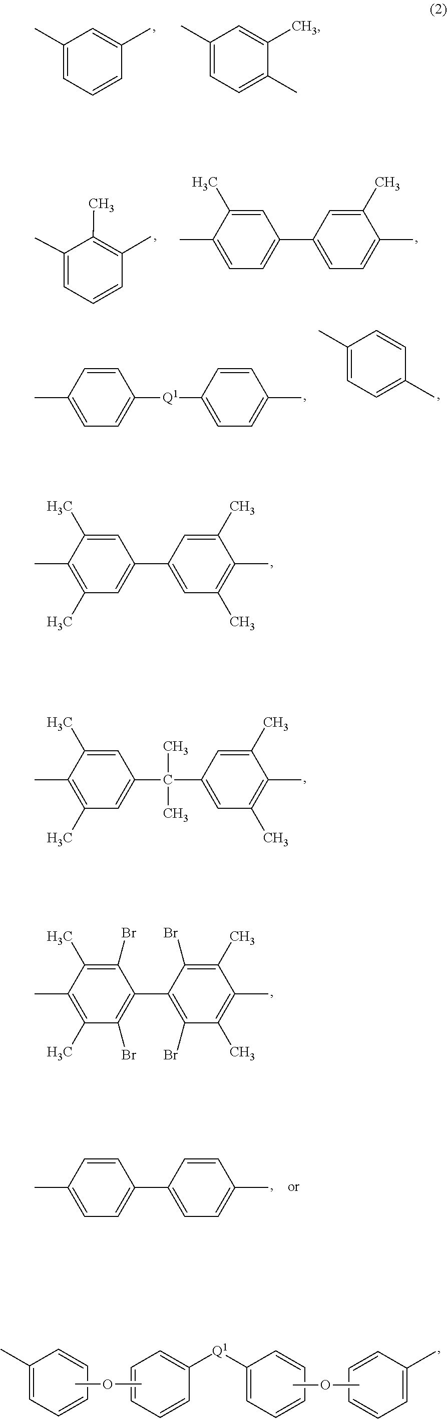

wherein Q¹ is —O—, —S—, —C(O)—, —SO₂—, —SO—, —P(R^{a})(═O)— wherein R^{a} is a C₁₋₈ alkyl or C₆₋₁₂ aryl, —C_{y}H_{2y}— wherein y is an integer from 1 to 5 or a halogenated derivative thereof (which includes perfluoroalkylene groups), or —(C₆H₁₀)_{z}— wherein z is an integer from 1 to 4. In an aspect R is m-phenylene, p-phenylene, or a diaryl sulfone.

Polyetherimides are a class of polyimides that comprise more than 1, for example 10 to 1000, or 10 to 500, structural units of formula (3)

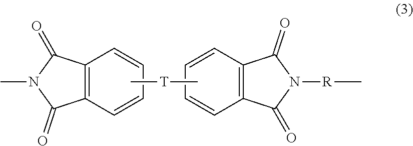

wherein each R is the same or different, and is as described in formula (1).

Further in formula (3), T is —O— or a group of the formula —O—Z—O— wherein the divalent bonds of the —O— or the —O—Z—O— group are in the 3,3′,3,4′,4,3′, or the 4,4′ positions. The group Z in —O—Z—O— of formula (3) is a substituted or unsubstituted divalent organic group, and can be an aromatic C₆₋₂₄ monocyclic or polycyclic moiety optionally substituted with 1 to 6 C₁₋₈ alkyl groups, 1 to 8 halogen atoms, or a combination comprising at least one of the foregoing, provided that the valence of Z is not exceeded. Exemplary groups Z include groups derived from a dihydroxy compound of formula (4)

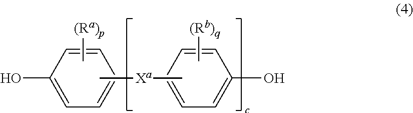

wherein R^{a} and R^{b} can be the same or different and are a halogen atom or a monovalent C₁₋₆ alkyl group, for example; p and q are each independently integers of 0 to 4; c is 0 to 4; and X^{a} is a bridging group connecting the hydroxy-substituted aromatic groups, where the bridging group and the hydroxy substituent of each C₆ arylene group are disposed ortho, meta, or para (specifically para) to each other on the C₆ arylene group. The bridging group X^{a} can be a single bond, —O—, —S—, —S(O)—, —S(O)₂—, —C(O)—, or a C₁₋₁₈ is organic bridging group. The C₁₋₁₈ organic bridging group can be cyclic or acyclic, aromatic or non-aromatic, and can further comprise heteroatoms such as halogens, oxygen, nitrogen, sulfur, silicon, or phosphorous. The C₁₋₁₈ organic group can be disposed such that the C₆ arylene groups connected thereto are each connected to a common alkylidene carbon or to different carbons of the C₁₋₁₈ organic bridging group. A specific example of a group Z is a divalent group of formula

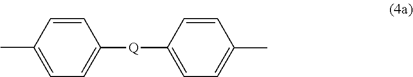

wherein Q is —O—, —S—, —C(O)—, —SO₂—, —SO—, or —C_{y}H_{2y}— wherein y is an integer from 1 to 5 or a halogenated derivative thereof (including a perfluoroalkylene group). In an aspect Z is a derived from bisphenol A, such that Q in formula (3a) is 2,2-isopropylidene.

In an aspect in formula (3), R is m-phenylene or p-phenylene and T is —O—Z—O— wherein Z is a divalent group of formula (4a). Alternatively, R is m-phenylene or p-phenylene and T is —O—Z—O— wherein Z is a divalent group of formula (4a) and Q is 2,2-isopropylidene.

In an aspect, the polyetherimide can be a copolymer, for example, a polyetherimide sulfone copolymer comprising structural units of formula (1) wherein at least 50 mole % of the R groups are of formula (2) wherein Q¹ is —SO₂— and the remaining R groups are independently p-phenylene or m-phenylene or a combination comprising at least one of the foregoing; and Z is 2,2′-(4-phenylene)isopropylidene.

Alternatively, the polyetherimide copolymer optionally comprises additional structural imide units, for example imide units of formula (1) wherein R and V are as described in formula (1), for example V is

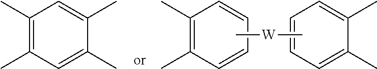

wherein W is a single bond, —O—, —S—, —C(O)—, —SO₂—, —SO—, a C₁₋₁₈ hydrocarbon moiety that can be cyclic, acyclic, aromatic, or non-aromatic, —P(R^{a})(═O)— wherein R^{a} is a C₁₋₈ alkyl or C₆₋₁₂ aryl, or —C_{y}H_{2y}— wherein y is an integer from 1 to 5 or a halogenated derivative thereof (which includes perfluoroalkylene groups). These additional structural imide units preferably comprise less than 20 mol % of the total number of units, and more preferably can be present in amounts of 0 to 10 mol % of the total number of units, or 0 to 5 mol % of the total number of units, or 0 to 2 mole % of the total number of units. In an aspect, no additional imide units are present in the polyetherimide. The polyimide and polyetherimide can be prepared by any of the methods well known to those skilled in the art, including the reaction of an aromatic bis(ether anhydride) of formula (5a) or formula (5b)

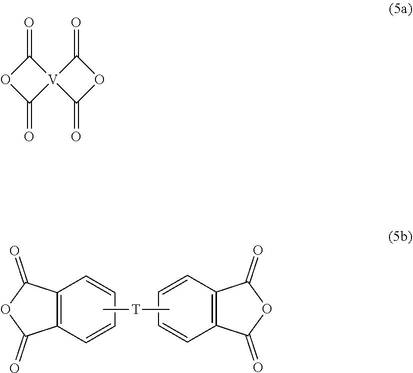

or a chemical equivalent thereof, with an organic diamine of formula (6)

H₂N—R—NH₂ (6)

wherein V, T, and R are defined as described above. Copolymers of the polyetherimides can be manufactured using a combination of an aromatic bis(ether anhydride) of formula (5) and a different bis(anhydride), for example a bis(anhydride) wherein T does not contain an ether functionality, for example T is a sulfone.

Illustrative examples of bis(anhydride)s include 3,3-bis[4-(3,4-dicarboxyphenoxy)phenyl]propane dianhydride; 4,4′-bis(3,4-dicarboxyphenoxy)diphenyl ether dianhydride; 4,4′-bis(3,4-dicarboxyphenoxy)diphenyl sulfide dianhydride; 4,4′-bis(3,4-dicarboxyphenoxy)benzophenone dianhydride; 4,4′-bis(3,4-dicarboxyphenoxy)diphenyl sulfone dianhydride; 2,2-bis[4-(2,3-dicarboxyphenoxy)phenyl]propane dianhydride; 4,4′-bis(2,3-dicarboxyphenoxy)diphenyl ether dianhydride; 4,4′-bis(2,3-dicarboxyphenoxy)diphenyl sulfide dianhydride; 4,4′-bis(2,3-dicarboxyphenoxy)benzophenone dianhydride; 4,4′-bis(2,3-dicarboxyphenoxy)diphenyl sulfone dianhydride; 4-(2,3-dicarboxyphenoxy)-4′-(3,4-dicarboxyphenoxy)diphenyl-2,2-propane dianhydride; 4-(2,3-dicarboxyphenoxy)-4′-(3,4-dicarboxyphenoxy)diphenyl ether dianhydride; 4-(2,3-dicarboxyphenoxy)-4′-(3,4-dicarboxyphenoxy)diphenyl sulfide dianhydride; 4-(2,3-dicarboxyphenoxy)-4′-(3,4-dicarboxyphenoxy)benzophenone dianhydride; and, 4-(2,3-dicarboxyphenoxy)-4′-(3,4-dicarboxyphenoxy)diphenyl sulfone dianhydride, as well as various combinations thereof.

Examples of organic diamines include hexamethylenediamine, polymethylated 1,6-n-hexanediamine, heptamethylenediamine, octamethylenediamine, nonamethylenediamine, decamethylenediamine, 1,12-dodecanediamine, 1,18-octadecanediamine, 3-methylheptamethylenediamine, 4,4-dimethylheptamethylenediamine, 4-methylnonamethylenediamine, 5-methylnonamethylenediamine, 2,5-dimethylhexamethylenediamine, 2,5-dimethylheptamethylenediamine, 2,2-dimethylpropylenediamine, N-methyl-bis(3-aminopropyl) amine, 3-methoxyhexamethylenediamine, 1,2-bis(3-aminopropoxy) ethane, bis(3-aminopropyl) sulfide, 1,4-cyclohexanediamine, bis-(4-aminocyclohexyl) methane, m-phenylenediamine, p-phenylenediamine, 2,4-diaminotoluene, 2,6-diaminotoluene, m-xylylenediamine, p-xylylenediamine, 2-methyl-4,6-diethyl-1,3-phenylene-diamine, 5-methyl-4,6-diethyl-1,3-phenylene-diamine, benzidine, 3,3′-dimethylbenzidine, 3,3′-dimethoxybenzidine, 1,5-diaminonaphthalene, bis(4-aminophenyl) methane, bis(2-chloro-4-amino-3,5-diethylphenyl) methane, bis(4-aminophenyl) propane, 2,4-bis(p-amino-t-butyl) toluene, bis(p-amino-t-butylphenyl) ether, bis(p-methyl-o-aminophenyl) benzene, bis(p-methyl-o-aminopentyl) benzene, 1,3-diamino-4-isopropylbenzene, bis(4-aminophenyl) sulfide, bis-(4-aminophenyl) sulfone (also known as 4,4′-diaminodiphenyl sulfone (DDS)), and bis(4-aminophenyl) ether. Any regioisomer of the foregoing compounds can be used. Combinations of these compounds can also be used. In an aspect the organic diamine is m-phenylenediamine, p-phenylenediamine, 4,4′-diaminodiphenyl sulfone, or a combination comprising at least one of the foregoing

The polyimide can include copolymers, for example including poly(siloxane-etherimide) copolymer comprising polyetherimide units of formula (1) and siloxane blocks of formula (7)

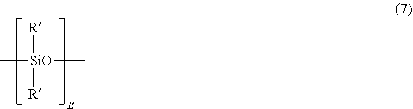

wherein E has an average value of 2 to 100, 2 to 31, 5 to 75, 5 to 60, 5 to 15, or 15 to 40, each R′ is independently a C₁₋₁₃ monovalent hydrocarbyl group. For example, each R′ can independently be a C₁₋₁₃ alkyl group, C₁₋₁₃ alkoxy group, C₂₋₁₃ alkenyl group, C₂₋₁₃ alkenyloxy group, C₃₋₆ cycloalkyl group, C₃₋₆ cycloalkoxy group, C₆₋₁₄ aryl group, C₆₋₁₀ aryloxy group, C₇₋₁₃ arylalkyl group, C₇₋₁₃ arylalkoxy group, C₇₋₁₃ alkylaryl group, or C₇₋₁₃ alkylaryloxy group. The foregoing groups can be fully or partially halogenated with fluorine, chlorine, bromine, or iodine, or a combination comprising at least one of the foregoing. In an aspect no bromine or chlorine is present, and in another aspect no halogens are present. Combinations of the foregoing R groups can be used in the same copolymer. In an aspect, the polysiloxane blocks comprises R′ groups that have minimal hydrocarbon content. In an aspect, an R′ group with a minimal hydrocarbon content is a methyl group.

The poly (siloxane-etherimide)s can be formed by polymerization of an aromatic bis(ether anhydride) of formula (5) and a diamine component comprising an organic diamine (6) as described above or a combination of diamines, and a polysiloxane diamine of formula (8)

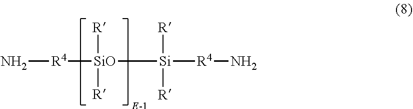

wherein R′ and E are as described in formula (7), and R⁴ is each independently a C₂-C₂₀ hydrocarbon, in particular a C₂-C₂₀ arylene, alkylene, or arylalkylene group. In an aspect R⁴ is a C₂-C₂₀ alkylene group, specifically a C₂-C₁₀ alkylene group such as propylene, and E has an average value of 5 to 100, 5 to 75, 5 to 60, 5 to 15, or 15 to 40. Procedures for making the polysiloxane diamines of formula (8) are well known in the art.

In some poly(siloxane-etherimide)s the diamine component can contain 10 to 90 mole percent (mol %), or 20 to 50 mol %, or 25 to 40 mol % of polysiloxane diamine (8) and 10 to 90 mol %, or 50 to 80 mol %, or 60 to 75 mol % of diamine (6), for example as described in U.S. Pat. No. 4,404,350. The diamine components can be physically mixed prior to reaction with the bisanhydride(s), thus forming a substantially random copolymer. Alternatively, block or alternating copolymers can be formed by selective reaction of (6) and (8) with aromatic bis(ether anhydrides (5), to make polyimide blocks that are subsequently reacted together. Thus, the poly(siloxane-imide) copolymer can be a block, random, or graft copolymer. In an aspect the copolymer is a block copolymer.

Examples of specific poly(siloxane-etherimide)s are described in U.S. Pat. Nos. 4,404,350, 4,808,686 and 4,690,997. In an aspect, the poly(siloxane-etherimide) has units of formula (9)

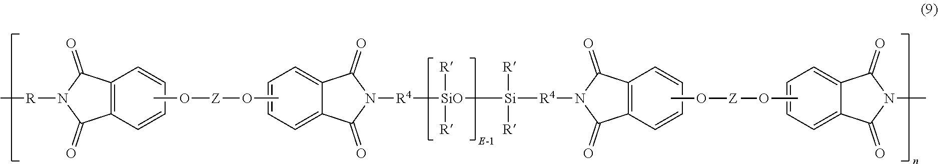

wherein R′ and E of the siloxane are as in formula (7), R and Z of the imide are as in formula (1), R⁴ is as in formula (8), and n is an integer from 5 to 100. In an aspect of the poly(siloxane-etherimide), R of the etherimide is a phenylene, Z is a residue of bisphenol A, R⁴ is n-propylene, E is 2 to 50, 5, to 30, or 10 to 40, n is 5 to 100, and each R′ of the siloxane is methyl.

The relative amount of polysiloxane units and etherimide units in the poly(siloxane-etherimide) depends on the desired properties, and are selected using the guidelines provided herein. In particular, as mentioned above, the block or graft poly(siloxane-etherimide) copolymer is selected to have a certain average value of E, and is selected and used in amount effective to provide the desired wt % of polysiloxane units in the composition. In an aspect the poly(siloxane-etherimide) comprises 10 to 50 wt %, 10 to 40 wt %, or 20 to 35 wt % polysiloxane units, based on the total weight of the poly(siloxane-etherimide). In an aspect, polyetherimide-siloxane can be excluded from the composition.

The polyimides/polyetherimides can have a melt index of 0.1 to 10 grams per minute (g/min), as measured by American Society for Testing Materials (ASTM) D1238 at 340 to 370° C., using a 6.7 kilogram (kg) weight. In an aspect, the polyetherimide has a weight average molecular weight (Mw) of 1,000 to 150,000 grams/mole (Dalton), as measured by gel permeation chromatography, using polystyrene standards. In an aspect the polyetherimide has an Mw of 10,000 to 80,000 Daltons. Such polyetherimides typically have an intrinsic viscosity greater than 0.2 deciliters per gram (dl/g), or, more specifically, 0.35 to 0.7 dl/g as measured in m-cresol at 25° C.

In an aspect, the composition can comprise a polyaryl ether sulfone as the high heat amorphous thermoplastic polymer, which are also referred to a polysulfones, polyether sulfones, and polyphenylene ether sulfones. Polyaryl ether sulfones are linear thermoplastic polymers that possess, for example, high temperature resistance, good electrical properties, and good hydrolytic stability. A variety of polyaryl ether sulfones are commercially available, including the polycondensation product of dihydroxy diphenyl sulfone with dichloro diphenyl sulfone and known as polyether sulfone (PES), and the polymer of bisphenol-A and dichloro diphenyl sulfone known in the art as polysulfone (PSU or PSF). Other polyaryl ether sulfones are the polybiphenyl ether sulfones, available from Solvay Inc. under the trademark of RADEL R resin. Polysulfones are also sold by Solvay Co. under the UDEL trade name. Polyethersulfones are sold by Solvay under the RADEL A trade names and by BASF, as ULTRASON E. A variety of PES copolymers, for example comprising bisphenol A (BPA) moieties, other bisphenols and diphenyl sulfone moieties in molar ratios other than 1:1, can also be found. Methods for the preparation of polyaryl ether sulfones are widely known. For example, two methods, the carbonate method, and the alkali metal hydroxide method, can be used. In the alkali metal hydroxide method, a double alkali metal salt of a dihydric phenol is contacted with a dihalobenzenoid compound in the presence of a dipolar, aprotic solvent under substantially anhydrous conditions. The carbonate method, in which at least one dihydric phenol and at least one dihalobenzenoid compound are heated, for example, with sodium carbonate or bicarbonate and a second alkali metal carbonate or bicarbonate is also disclosed in the art, for example in U.S. Pat. No. 4,176,222. Alternatively, the polybiphenyl ether sulfone, PSU and PES components can be prepared by any of the variety of methods known in the art for the preparation of polyaryl ether resins.

The molecular weight of the polysulfone, as indicated by reduced viscosity data in an appropriate solvent such as methylene chloride, chloroform, N-methylpyrrolidone, or the like, can be at least 0.3 dl/g, preferably at least 0.4 dl/g and, typically, will not exceed about 1.5 dl/g. In some instances the polysulfone weight average molecular weight can vary from 10,000 to 100,000 grams per mole as determined by gel permeation chromatography. Polysulfones can have glass transition temperatures from 180 to 250° C. in some instances.

The thermoplastic polysulfones, polyethersulfones and polyphenylene ether sulfones polyethersulfones can be prepared as described in U.S. Pat. Nos. 3,634,355, 4,008,203, 4,108,837 and 4,175,175, each of which is incorporated by reference herein in its entirety.

In an aspect, the high heat amorphous thermoplastic polymer is a polyetherimide, a poly(phenylsulfone), or a combination thereof, preferably a polyetherimide or a combination of a polyetherimide and a poly(phenylsulfone).

The high heat amorphous thermoplastic polymer can be present in the composition in an amount of 30 to 94 weight percent, based on the total weight of the composition. Within this range, the high heat amorphous thermoplastic polymer can be present in an amount of 50 to 94 weight percent, or 60 to 90 weight percent, or 65 to 85 weight percent.

In addition to the high heat amorphous thermoplastic polymer, the composition further comprises a flow promoter comprising a polyester, a poly(carbonate-ester), an aromatic polyketone, a poly(phenylene sulfide), or a combination thereof.

The polyester can preferably be a poly(alkylene terephthalate). The alkylene group of the poly(alkylene terephthalate) can comprise 2 to 18 carbon atoms. Examples of alkylene groups are ethylene, 1,3-propylene, 1,4-butylene, 1,5-pentylene, 1,6-hexylene, 1,4-cyclohexylene, 1,4-cyclohexanedimethylene, and combinations thereof. In an aspect, the alkylene group comprises ethylene, 1,4-butylene, or a combination thereof, and the poly(alkylene terephthalate comprises poly(ethylene terephthalate), poly(butylene terephthalate), or a combination thereof, respectively. In an aspect, the alkylene group comprises ethylene and the poly(alkylene terephthalate) comprises poly(ethylene terephthalate).

Poly(carbonate-ester)s, also known as poly(ester-carbonates), comprise recurring carbonate repeating units of formula (10)

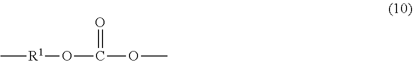

wherein at least 60 percent of the total number of R′ groups are aromatic, or each R′ contains at least one C₆₋₃₀ aromatic group. Preferably, each R′ can be derived from a dihydroxy compound such as an aromatic dihydroxy compound of formula (11) or a bisphenol of formula (12).

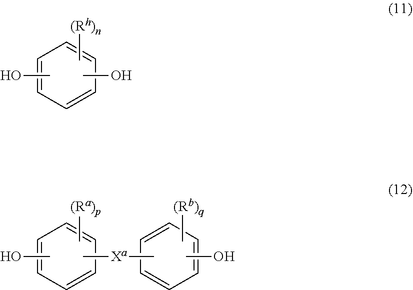

In formula (2), each R^{h} is independently a halogen atom, for example bromine, a C₁₋₁₀ hydrocarbyl group such as a C₁₋₁₀ alkyl, a halogen-substituted C₁₋₁₀ alkyl, a C₆₋₁₀ aryl, or a halogen-substituted C₆₋₁₀ aryl, and n is 0 to 4.

In formula (12), R^{a} and R^{b} are each independently a halogen, C₁₋₁₂ alkoxy, or C₁₋₁₂ alkyl, and p and q are each independently integers of 0 to 4, such that when p or q is less than 4, the valence of each carbon of the ring is filled by hydrogen. In an aspect, p and q is each 0, or p and q is each 1, and R^{a} and R^{b} are each a C₁₋₃ alkyl group, preferably methyl, disposed meta to the hydroxy group on each arylene group. X^{a} is a bridging group connecting the two hydroxy-substituted aromatic groups, where the bridging group and the hydroxy substituent of each C₆ arylene group are disposed ortho, meta, or para (preferably para) to each other on the C₆ arylene group, for example, a single bond, —O—, —S—, —S(O)—, —S(O)₂—, —C(O)—, or a C₁₋₁₈ organic group, which can be cyclic or acyclic, aromatic or non-aromatic, and can further comprise heteroatoms such as halogens, oxygen, nitrogen, sulfur, silicon, or phosphorous. For example, X^{a} can be a substituted or unsubstituted C₃₋₁₈ cycloalkylidene; a C₁₋₂₅ alkylidene of the formula —C(R^{c})(R^{d})— wherein R^{c} and R^{d} are each independently hydrogen, C₁₋₁₂ alkyl, C₁₋₁₂ cycloalkyl, C₇₋₁₂ arylalkyl, C₁₋₁₂ heteroalkyl, or cyclic C₇₋₁₂ heteroarylalkyl; or a group of the formula —C(═Rₑ)— wherein R^{e} is a divalent C₁₋₁₂ hydrocarbon group.

In addition to units according to formula (10), the poly(carbonate-ester) further comprises repeating ester units of formula (13)

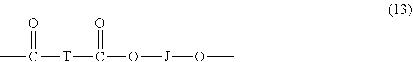

wherein J is a divalent group derived from a dihydroxy compound (which includes a reactive derivative thereof), and can be, for example, a C₁₋₁₀ alkylene, a C₆₋₂₀ cycloalkylene, a C₅₋₂₀ arylene, or a polyoxyalkylene group in which the alkylene groups contain 2 to 6 carbon atoms, preferably, 2, 3, or 4 carbon atoms; and T is a divalent group derived from a dicarboxylic acid (which includes a reactive derivative thereof), and can be, for example, a C₁₋₂₀ alkylene, a C₅₋₂₀ cycloalkylene, or a C₆₋₂₀ arylene. Copolyesters containing a combination of different T or J groups can be used. The polyester units can be branched or linear.

Specific dihydroxy compounds include aromatic dihydroxy compounds of formula (11) (e.g., resorcinol), bisphenols of formula (12) (e.g., bisphenol A), a C₁₋₈ aliphatic diol such as ethane diol, n-propane diol, i-propane diol, 1,4-butane diol, 1,4-cyclohexane diol, 1,4-hydroxymethylcyclohexane, or a combination thereof dihydroxy compounds. Aliphatic dicarboxylic acids that can be used include C₅₋₂₀ aliphatic dicarboxylic acids (which includes the terminal carboxyl groups), preferably linear C₈₋₁₂ aliphatic dicarboxylic acid such as decanedioic acid (sebacic acid); and alpha, omega-C₁₂ dicarboxylic acids such as dodecanedioic acid (DDDA). Aromatic dicarboxylic acids that can be used include terephthalic acid, isophthalic acid, naphthalene dicarboxylic acid, 1,4-cyclohexane dicarboxylic acid, or a combination thereof acids. A combination of isophthalic acid and terephthalic acid wherein the weight ratio of isophthalic acid to terephthalic acid is 91:9 to 2:98 can be used.

Specific ester units include ethylene terephthalate units, n-proplyene terephthalate units, n-butylene terephthalate units, ester units derived from isophthalic acid, terephthalic acid, and resorcinol (ITR ester units), and ester units derived from sebacic acid and bisphenol A. The molar ratio of ester units to carbonate units in the poly(ester-carbonate)s can vary broadly, for example 1:99 to 99:1, preferably, 10:90 to 90:10, more preferably, 25:75 to 75:25, or from 2:98 to 15:85. In some aspects the molar ratio of ester units to carbonate units in the poly(ester-carbonate)s can vary from 1:99 to 30:70, preferably 2:98 to 25:75, more preferably 3:97 to 20:80, or from 5:95 to 15:85.

The aromatic poly(ketone) comprises repeating units of formula (14)

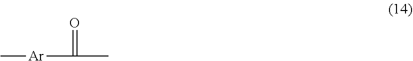

wherein Ar is independently at each occurrence a substituted or unsubstituted, monocyclic or polycyclic aromatic group having 6-30 carbons. Exemplary Ar groups include, but are not limited to, substituted or unsubstituted phenyl, tolyl, naphthyl, and biphenyl. Unsubstituted phenyl is preferred. In an aspect, the aromatic poly(ketone) can be a poly(arylene ether ketone) (PAEK) comprising repeating units of formula (14) and formula (15)

—Ar—O— (15)

wherein Ar is defined as above. In an aspect the aromatic polyketone comprises a poly(ether ketone). A poly(ether ketone) comprises repeating units of formula (16)

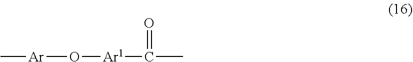

wherein Ar is defined as above and Ar¹ is independently at each occurrence a substituted or unsubstituted, monocyclic or polycyclic aromatic group having 6-30 carbons. Ar can be the same as or different from Ar¹. In an aspect Ar and Ar¹ are phenyl groups, preferably unsubstituted phenyl groups.

In an aspect, the aromatic poly(ketone) comprises a poly(ether ether ketone). A poly(ether ether ketone) comprises repeating units of formula (17)

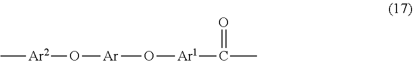

wherein Ar and Ar¹ are defined as above. Ar² is independently at each occurrence a substituted or unsubstituted, monocyclic or polycyclic aromatic group having 6-30 carbons. Ar, Ar¹, and Ar² can be the same as or different from each other. Additionally, two of Ar, Ar¹, and Ar² can be the same as each other and the third can be different. In an aspect Ar, Ar¹, and Ar² are phenyl groups, preferably unsubstituted phenyl groups.

Poly(arylene ether ketone)s are generally known, with many examples being commercially available. Examples of commercially available aromatic poly(ketone)s include those sold under the trade name PEEK™, available from VICTREX.

In an aspect, the aromatic poly(ketone) comprises a poly(ether ketone), poly(ether ether ketone), poly(ether ketone ketone), or a combination comprising at least one of the foregoing, preferably a poly(ether ether ketone) of formula (17).

In an aspect, the flow promoter can preferably comprise poly(ethylene terephthalate), poly(butylene terephthalate), an (isophthalate-terephthalate-resorcinol)-carbonate copolymer, poly(ether ether ketone), poly(phenylene sulfide), or a combination thereof, more preferably a poly(ethylene terephthalate), a poly(ether ether ketone), a poly(phenylene sulfide), or a combination thereof. In an aspect, the flow promoter comprises poly(ether ether ketone).

The flow promoter can be present in the composition in an amount of 1 to 15 weight percent, based on the total weight of the composition. Within this range, the flow promoter can be present in an amount of 1 to 12 weight percent, or 3 to 12 weight percent.

In addition to the high heat, amorphous thermoplastic polymer and the flow promoter, the composition includes a mineral filler. Particular mineral fillers which are suitable for use in the composition can include, for example, talc, wollastonite, clay (e.g., kaolin clay), and the like, or a combination thereof. In an aspect, the mineral filler comprises talc, kaolin clay, wollastonite, or a combination thereof. In an aspect, the mineral filler comprises talc. The mineral filler can have any morphology, such as fibrous, modular, needle shaped, lamellar, or spherical. In an aspect, the mineral filler can have an average particle size of less than 10 micrometers, preferably less than 2 micrometers. Average particle size can also be referred to as median particle size or “D50”.

The mineral filler can be included in the composition in an amount of 1 to 40 weight percent, based on the total weight of the composition. Within this range, the mineral filler can be present in an amount of 3 to 30 weight percent, or 5 to 30 weight percent, or 5 to 25 weight percent, or 5 to 20 weight percent.

In addition to the high heat, amorphous thermoplastic polymer, the flow promoter, and the mineral filler, the composition can optionally further include a poly(phenylene ether) oligomer. The poly(phenylene ether) oligomer comprises repeating structural units have the formula (18)

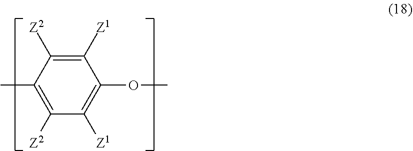

wherein each occurrence of Z¹ is independently halogen, unsubstituted or substituted C₁₋₁₂ hydrocarbyl provided that the hydrocarbyl group is not tertiary hydrocarbyl, C₁₋₁₂ hydrocarbylthio, C₁₋₁₂ hydrocarbyloxy, or C₂₋₁₂ halohydrocarbyloxy wherein at least two carbon atoms separate the halogen and oxygen atoms; and each occurrence of Z² is independently hydrogen, halogen, unsubstituted or substituted C₁₋₁₂ hydrocarbyl provided that the hydrocarbyl group is not tertiary hydrocarbyl, C₁₋₁₂ hydrocarbylthio, C₁₋₁₂ hydrocarbyloxy, or C₂₋₁₂ halohydrocarbyloxy wherein at least two carbon atoms separate the halogen and oxygen atoms.

In an aspect, the poly(phenylene ether) oligomer comprises 2,6-dimethyl-1,4-phenylene ether units, 2,3,6-trimethyl-1,4-phenylene ether units, or a combination thereof. In an aspect, the poly(phenylene ether) oligomer is a poly(2,6-dimethyl-1,4-phenylene ether) oligomer. In an aspect, the poly(phenylene ether) oligomer comprises a poly(2,6-dimethyl-1,4-phenylene ether) oligomer having an intrinsic viscosity of 0.03 to 0.2 deciliter per gram, or 0.03 to 0.13 deciliter per gram, or 0.08 to 0.15 deciliter per gram, or 0.05 to 0.1 deciliter per gram, or 0.1 to 0.15 deciliter per gram. Intrinsic viscosity can be measured at 25° C. in chloroform using an Ubbelohde viscometer. The poly(phenylene ether) oligomer can have a number average molecular weight of 500 to 7,000 grams per mole, and a weight average molecular weight of 500 to 15,000 grams per mole, as determined by gel permeation chromatography using polystyrene standards. In an aspect, the number average molecular weight can be 750 to 4,000 grams per mole, and the weight average molecular weight can be 1,500 to 9,000 grams per mole, as determined by gel permeation chromatography using polystyrene standards.

In an aspect, the poly(phenylene ether) oligomer can be monofunctional or bifunctional. The oligomeric poly(phenylene ether) can be monofunctional. For example, it can have a functional group at one terminus of the polymer chains. The functional group can be, for example, a hydroxyl group or a (meth)acrylate group. In an aspect, the oligomeric poly(phenylene ether) comprises poly(2,6-dimethyl-1,4-phenylene ether). An example of a monofunctional oligomeric poly(2,6-dimethyl-1,4-phenylene ether) is NORYL™ SA120, available from SABIC. In an aspect, the poly(phenylene ether) oligomer can be bifunctional and can have functional groups at both termini of the oligomer chain. The functional groups can be, for example, hydroxyl groups or (meth)acrylate groups, preferably (meth)acrylate groups. Bifunctional polymers with functional groups at both termini of the polymer chains are also referred to as “telechelic” polymers. In an aspect, the poly(phenylene ether) oligomer comprises a bifunctional poly(phenylene ether) oligomer having the structure (19)

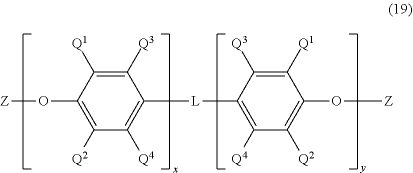

wherein Q¹ and Q² each independently comprise halogen, unsubstituted or substituted C₁₋₁₂ primary or secondary hydrocarbyl, C₁-C₁₂ hydrocarbylthio, C₁-C₁₂ hydrocarbyloxy, and C₂₋₁₂ halohydrocarbyloxy wherein at least two carbon atoms separate the halogen and oxygen atoms; each occurrence of Q³ and Q⁴ independently comprise hydrogen, halogen, unsubstituted or substituted C₁₋₁₂ primary or secondary hydrocarbyl, C₁₋₁₂ hydrocarbylthio, C₁₋₁₂ hydrocarbyloxy, and C₂₋₁₂ halohydrocarbyloxy wherein at least two carbon atoms separate the halogen and oxygen atoms; Z is hydrogen or (meth)acrylate; x and y are independently 0 to 30, specifically 0 to 20, more specifically 0 to 15, still more specifically 0 to 10, even more specifically 0 to 8, provided that the sum of x and y is at least 2, specifically at least 3, more specifically at least 4; and L has the structure (20)

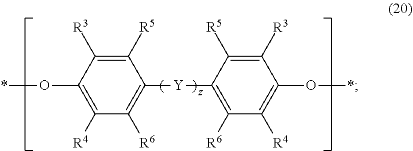

wherein each occurrence of R³ and R⁴ and R⁵ and R⁶ is independently hydrogen, halogen, unsubstituted or substituted C₁₋₁₂ primary or secondary hydrocarbyl, C₁₋₁₂ hydrocarbylthio, C₁₋₁₂ hydrocarbyloxy, and C₂₋₁₂ halohydrocarbyloxy wherein at least two carbon atoms separate the halogen and oxygen atoms; z is 0 or 1; and Y has a structure comprising

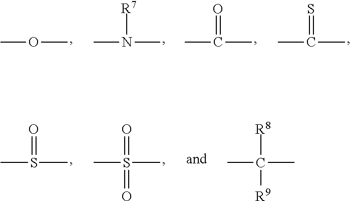

wherein each occurrence of R⁷ is independently hydrogen and C₁₋₁₂ hydrocarbyl, and each PGP-4 occurrence of R⁸ and R⁹ is independently hydrogen, C₁₋₁₂ hydrocarbyl, and C₁₋₆ hydrocarbylene wherein R⁸ and R⁹ collectively form a C₄₋₁₂ alkylene group.

In an aspect the poly(phenylene ether) oligomer comprises a bifunctional poly(phenylene ether) oligomer having the structure (21)

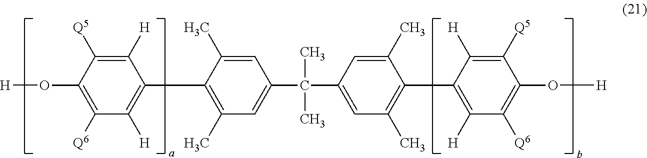

wherein each occurrence of Q⁵ and Q⁶ is independently methyl, di-n-butylaminomethyl, or morpholinomethyl; and each occurrence of a and b is independently 0 to 20, with the proviso that the sum of a and b is at least 2. An exemplary bifunctional poly(phenylene ether) oligomer includes NORYL™ SA90, available from SABIC.

The poly(phenylene ether) oligomer can be present in an amount of 0 to 6 weight percent, based on the total weight of the composition. When present, the poly(phenylene ether) oligomer can be present in an amount of greater than 0 to 6 weight percent. Within this range, the poly(phenylene ether) oligomer can be present in an amount of greater than 0 to 5 weight percent, or 1 to 5 weight percent, or 1 to 4 weight percent.

The composition can optionally further include an additive. Additives can be selected to achieve a desired property, with the proviso that the additives are also selected so as to not significantly adversely affect a desired property of the composition. Any additives can be mixed at a suitable time during the mixing of the components for forming the composition. Exemplary additives can include, for example, an impact modifier, flow modifier, reinforcing agent (e.g., glass fibers), antioxidant, heat stabilizer, light stabilizer, ultraviolet (UV) light stabilizer, UV absorbing additive, plasticizer, lubricant, release agent (such as a mold release agent), antistatic agent, anti-fog agent, antimicrobial agent, colorant (e.g., a dye or pigment), surface effect additive, radiation stabilizer, flame retardant, anti-drip agent (e.g., a PTFE-encapsulated styrene-acrylonitrile copolymer (TSAN)), or a combination thereof. In an aspect, the additive can be a thermal stabilizer, a mold release agent, a flame retardant, a colorant, or a combination thereof. The additives are used in the amounts generally known to be effective. For example, the total amount of any additives (other than any impact modifier or reinforcing agent) can be 0.001 to 10.0 weight percent, or 0.01 to 5 weight percent, each based on the total weight of the polymer in the composition.

In an aspect, the composition can exclude glass fibers. When glass fibers are included, the flowability of the composition can be adversely affected, which is generally not desirable for molding thin parts, such as in consumer electronics applications. Furthermore, glass fibers can contribute to undesirable surface defects in molded parts.

The composition of the present disclosure can advantageously exhibit one or more desirable properties. For example, the composition can have a melt viscosity of less than 320 Pa·s at a temperature of 337° C. and a shear rate of 5000 s¹. The composition can have a flexural modulus of greater than 3000 MPa. The composition can have a heat deflection temperature of greater than 150° C. The composition can have a surface roughness of less than 0.4 μm.

The composition can be prepared by methods that are generally known. For example, the composition can be made by melt-mixing the components of the composition. The composition can further be molded into useful shapes by a variety of techniques such as injection molding, extrusion, rotational molding, blow molding, and thermoforming to form articles. Thus the thermoplastic compositions can be used to form a foamed article, a molded article, a thermoformed article, an extruded film, an extruded sheet, a layer of a multi-layer article, e.g., a cap-layer, a substrate for a coated article, or a substrate for a metallized article. The articles can have a wide range of thicknesses, for example from 0.1 to 10 mm, or 0.5 to 5 mm.

The composition of the present disclosure can be particularly useful for preparing articles comprising the composition as described above and a metal layer disposed on a surface of the composition. The composition can be in the form of a molded part as described above.

The metal layer can be deposited on the surface of the molded part comprising the composition by direct physical vapor deposition (PVD) or by a combination of electroless plating, electroplating, and physical vapor deposition. For example, the metal layer can be deposited by electroless plating, followed by electroplating, followed by physical vapor deposition.

The metal layer can comprise copper (Cu), nickel (Ni), chromium (Cr), gold (Au), titanium (Ti), tungsten (W), a compound thereof (e.g., TiCr, TiN, TiC, TiSi, TiO, CiC, CrN, CrO, WC, WCr, WN, WO, and the like), or a combination thereof. In an aspect, the metal layer can preferably comprise Cr, Ni, Cu, TiCr, TiN, TiC, TiSi, TiO, CiC, CrN, CrO, WC, WCr, WN, WO, or a combination thereof.

In an aspect, a metal layer deposited by electroless plating comprises Cu, Ni, or a combination thereof. In an aspect, a metal layer deposited by electroplating comprises Cu, Ni, Cr, or a combination thereof. In an aspect, a metal layer deposited by physical vapor deposition comprises Cr, Cu, Au, Ti, W, a compound thereof, or a combination thereof.

The metal layer can have a thickness of 1 to 100 micrometers, preferably 1 to 55 micrometers.

The metal layer of the article can exhibit a vibration resistance of at least ten minutes. The metal layer of the article can exhibit a cross-hatch adhesion test classification of at least 4B. The metal layer of the article can exhibit a corrosion resistance of at least 48 hours as determined by a salt spray test according to ASTM B 117.

As described above, the article of the present disclose can generally be any article molded from the composition and having a metal layer disposed thereon. In particular, the article can be a component of a consumer electronic device. In an aspect, the article can be a frame for eyewear.

The articles of the present disclosure can be prepared by preparing the composition according to the above described method (e.g., melt mixing the compositions of the composition), molding the composition, and depositing a metal layer on a surface of the molded composition, where depositing the metal layer can be by electroless plating, electroplating, physical vapor deposition, or a combination thereof. In an aspect, depositing the metal layer is by physical vapor deposition. In an aspect, depositing the metal layer is by a specific combination of electroless plating, electroplating, and physical vapor deposition, where each technique is used sequentially in the order defined above.

Accordingly, the present disclosure provides particular thermoplastic compositions which can be especially useful in provided metallized articles. The metallized articles can exhibit a unique combination of physical properties which make them particularly well-suited for applications in consumer electronics. Accordingly, a substantial improvement is provided by the present disclosure.

This disclosure is further illustrated by the following examples, which are non-limiting.

### EXAMPLES

The materials used in the following examples are described in Table 1.

TABLE 1

| Component | Description | Supplier |
|---|---|---|
| PEI-Si | Polyetherimide-siloxane copolymer comprising structural units derived from | SABIC |
| | bisphenol A dianhydride, m-phenylene diamine, and 34 weight percent bis(3- | |
| | aminopropyl(polydimethylsiloxane, and having a weight average molecular | |
| | weight (M_{w}) of 67,000 Daltons (Da); CAS Reg. No. 99904-16-2; obtained as | |
| | SILTEM 1500 | |
| PEI-1 | Polyetherimide comprising structural units derived from bisphenol A dianhydride | SABIC |
| | and m-phenylene diamine, and having a weight average molecular weight (M_{w}) of | |
| | 54,000 Daltons (Da); CAS Reg. No. 61128-46-9; obtained as ULTEM 1000. | |
| PEI-2 | Polyetherimide comprising structural units derived from bisphenol A dianhydride | SABIC |
| | and m-phenylene diamine, and aniline end-caps; CAS Reg. No. 61128-46-9; | |
| | obtained as ULTEM 1010K. | |
| PPSU | Polyphenylene sulfone resin (CAS Reg. No. 31833-61-1); obtained as Paryls ® | UJU |
| | F1350 | |
| PPE | Poly(2,6-dimethyl-1,4-phenylene ether) having an intrinsic viscosity of 0.12 | SABIC |
| | deciliter per gram (dL/g) as measured at 25° C. in chloroform, obtained as | |
| | NORYL SA120 | |
| PEPQ | Reaction products of phosphorus trichloride with 1,1′-biphenyl and 2,4-bis(1,1- | Clariant |
| | dimethylethyl)phenol, CAS Reg. No. 119345-01-6; obtained as HOSTANOX ™ | |
| | P-EPQ ™ | |
| TBPP | Tris(2,4-di-tert-butylphenyl) phosphite, CAS Reg. No. 31570-04-4; obtained as | BASF |
| | IRGAFOS ™ 168 | |
| Talc | Talc, obtained as Jetfine 3CA | IMERYS |
| Clay | Kaolin clay obtained as KaMin ™ HG90 | KAMIN |
| Wollastonite | CAS Reg. No. 13983-17-0) coated with a silane layer; obtained as Wollastonite | IMERYS |
| | 4w | |
| GF | Chopped glass fibers having a diameter of 10 micrometers, a pre-compounded | Owens |
| | length of 4 millimeters; obtained as Advantex 910A | Corning |
| PET | Poly(ethylene terephthalate) (CAS Reg. No. 25038-59-9) having an intrinsic | FOSU |
| | viscosity of 0.565 deciliter per gram measured by Ubbelohde viscometer at 25° C. | |
| | in a 1:1 weight/weight mixture of phenol and 1,1,2,2-tetrachloroethane; obtained | |
| | as FC-03-56 | |
| PBT | Poly(1,4-butylene terephthalate), CAS Reg. No. 26062-94-2, having an intrinsic | Changchun |
| | viscosity of 1.23-1.30 deciliters/gram and a carboxylic acid (COOH) end group | plastic |
| | content of 33-40 milliequivalents COOH per kilogram resin; obtained as CPP PBT | |
| | 1100X | |
| LCP | Aromatic liquid crystalline polyether (CAS Reg. No. 90967-43-4), obtained as | UENO |
| | UNEO LCP A2500 | |
| PEEK | Poly(ether ether ketone) commercially available as PEEK 330G | Zhongyan |
| ITR-PC | A block poly(ester-carbonate), CAS Reg. No. 235420-85-6, comprising 81 mole | SABIC |
| | percent resorcinol iso-/terephthalate ester linkages, 8 mole % resorcinol carbonate | |
| | linkages, and 11 mole % bisphenol A carbonate linkages, having a glass transition | |
| | temperature of 142° C. | |
| PPS | Poly(phenylsulfide) (CAS Reg. No. 26125-40-6), obtained as NHU-PPS-3470 | NHU |

Compositions for the following examples were prepared by compounding on a Toshiba TEM-37BS twin screw extruder. All materials were blended together and fed by the main feeder. The compounding profile for each example is described in Table 2.

TABLE 2

| | | | | E1-E9 | | | |
|---|---|---|---|---|---|---|---|
| Parameters | Unit | C1 | C2-C4 | and E11 | E10 | E12-E13 | E14-E15 |
| Zone 1 Temp | ° C. | 50 | 50 | 50 | 50 | 50 | 50 |
| Zone 2 Temp | ° C. | 150 | 150 | 150 | 150 | 150 | 150 |
| Zone 3 Temp | ° C. | 280 | 300 | 300 | 300 | 320 | 300 |
| Zone 4 Temp | ° C. | 295 | 360 | 320 | 340 | 370 | 350 |
| Zone 5 Temp | ° C. | 295 | 360 | 320 | 340 | 370 | 350 |
| Zone 6 Temp | ° C. | 295 | 360 | 320 | 340 | 370 | 350 |
| Zone 7 Temp | ° C. | 295 | 360 | 320 | 340 | 370 | 350 |
| Zone 8 Temp | ° C. | 295 | 360 | 320 | 340 | 370 | 350 |
| Zone 9 Temp | ° C. | 295 | 360 | 320 | 340 | 370 | 350 |
| Zone 10 Temp | ° C. | 295 | 360 | 320 | 340 | 370 | 350 |
| Zone 11 Temp | ° C. | 295 | 360 | 320 | 340 | 370 | 350 |
| Die Temp | ° C. | 295 | 360 | 320 | 340 | 370 | 350 |
| Screw speed | rpm | 400 | 400 | 400 | 400 | 500 | 500 |
| Throughput | kg/hr | 30 | 30 | 30 | 30 | 30 | 40 |

The resulting strand of the composition was cut into pellets and dried for further molding and evaluation. The testing described below was conducted on pellets and molded parts. Injection molding was done using a Fanuc S-2000i injection molding machine equipped with an Axxicon tool. The injection molding profile for each example is described in Table 3.

TABLE 3

| | | | | E1-E10 | |
|---|---|---|---|---|---|
| | | | | and | |
| Parameters | Unit | C1 | C2-C4 | E14-E15 | E12-E13 |
| Cnd: Pre-drying | Hour | 6 | 4 | 4 | 4 |
| time | | | | | |
| Cnd: Pre-drying | ° C. | 105 | 150 | 135 | 150 |
| temp | | | | | |
| Hopper temp | ° C. | 50 | 50 | 50 | 50 |
| Zone 1 temp | ° C. | 330 | 300 | 300 | 300 |
| Zone 2 temp | ° C. | 330 | 370 | 350 | 380 |
| Zone 3 temp | ° C. | 330 | 370 | 350 | 380 |
| Nozzle temp | ° C. | 330 | 370 | 350 | 380 |
| Mold temp | ° C. | 80 | 150 | 150 | 180 |
| Screw speed | rpm | 80 | 80 | 80 | 80 |
| Back pressure | kgf/cm² | 100 | 100 | 100 | 100 |
| Decompression | mm | 5 | 5 | 5 | 5 |
| Injection time | s | 3 | 3 | 3 | 3 |
| Holding time | s | 10 | 10 | 10 | 10 |
| Cooling time | s | 30 | 30 | 30 | 30 |
| Shot volume | mm | 35 | 35 | 35 | 35 |
| Switch point(mm) | mm | 10 | 10 | 10 | 10 |
| Injection | mm/s | 60 | 60 | 60 | 60 |
| speed(mm/s) | | | | | |
| Holding pressure | kgf/cm² | 1100 | 1100 | 1100 | 1100 |
| Cushion | mm | 4.3 | 4.3 | 4.3 | 4.3 |

Properties of the compositions were tested according to the following test methods. Heat deflection temperature (HDT) was determined according to ASTM D648 using a testing stress of 1.82 MPa and a specimen thickness of 3.2 millimeters. Notched and Unnotched Izod Impact Strength was determined according to ASTM D256 using a pendulum energy of 5 pound force/foot (lbf/ft) at 23° C. Tensile properties were determined according to ASTM D638 using a testing speed of 50 mm/min. Flexural properties were determined according to ASTM D790 using a testing speed of 1.27 mm/min. Melt viscosity (MV) was determined according to ISO11443 at a temperature of 337° C. at a shear rate of 5000 s⁻¹. Roughness was determined by a roughness meter. Adhesion was determined by a tape cross hatch test according to ASTM D3359. Corrosion resistance was determined using a salt spray test according to ASTM B 117. Adhesion was further tested by boiling for 30 minutes at 80° C. and subsequently testing the adhesion according to ASTM D3359. Vibration resistance was tested using a Germany Rosler vibration wear testing machine R180/530.

Metallization on the molded parts was conducted using (1) direct physical vapor deposition, or (2) electroless plating plus electroplating plus physical vapor deposition (i.e., where a metal layer is deposited directly on the molded part by electroless plating, a second metal layer is deposited on the first metal layer by electroplating, and a third metal layer is deposited on the second metal layer by physical vapor deposition. In the following examples, the electroless plated layers comprise Cu or Ni; the electroplating layer comprises Cu, Ni, Cr, or a combination thereof; and the physical vapor deposition layer comprises Cr, Cu, Au, Ti, W, Si, a compound thereof, or a combination thereof.

Compositions and properties for the examples are shown in Table 4. Amounts of all components of the composition are in weight percent, based on the total weight of the composition.

TABLE 4

| | Unit | C1 | C2 | C3 | C4 | E1 | E2 | E3 | E4 | E5 |
|---|---|---|---|---|---|---|---|---|---|---|
| Component | | | | | | | | | | |
| PEI-Si | wt % | 100 | | | | | | | | |
| PEI-1 | wt % | | 95.8 | 85.8 | | | | | | |
| PEI-2 | wt % | | | | 80.8 | 77.8 | 75.8 | 55.8 | 79.3 | 80.8 |
| PPSU | wt % | | | | | | | | | |
| PPE | wt % | | 4 | 4 | 4 | 4 | 4 | 4 | 2.5 | 1 |
| PEPQ | wt % | | 0.1 | 0.1 | 0.1 | 0.1 | 0.1 | 0.1 | 0.1 | 0.1 |
| TBPP | wt % | | 0.1 | 0.1 | 0.1 | 0.1 | 0.1 | 0.1 | 0.1 | 0.1 |
| Talc | wt % | | | | 10 | 15 | 15 | 30 | 15 | 15 |
| Clay | wt % | | | | | | | | | |
| Wollastonite | wt % | | | | | | | | | |
| GF | wt % | | | 10 | | | | | | |
| PET | wt % | | | | | 3 | 5 | 10 | 3 | 3 |
| PBT | wt % | | | | | | | | | |
| LCP | wt % | | | | 5 | | | | | |
| PEEK | wt % | | | | | | | | | |
| ITR-PC | wt % | | | | | | | | | |
| PPS | wt % | | | | | | | | | |
| Properties | | | | | | | | | | |
| HDT | ° C. | 80 | 186 | 199 | 187 | 177 | 177 | 161 | 178 | 181 |
| Flex. Mod. | MPa | 327 | 3320 | 5140 | 4500 | 5380 | 5270 | 7930 | 5200 | 5180 |
| Flex. Stress | MPa | 10.4 | 163 | 194 | 159 | 175 | 159 | 136 | 144 | 182 |
| Notched | J/m | 250 | 51.8 | 43 | 36.2 | 35.5 | 30.8 | 34.1 | 32 | 32.1 |
| Izod Impact | | | | | | | | | | |
| Unnotched | J/m | NB | 1545 | 246 | 628 | 691 | 444 | 333 | 589 | 559 |
| Izod Impact | | | | | | | | | | |
| Tens. Mod. | MPa | 419 | 3309 | 5333 | 4933 | 5922 | 5664 | 8537 | 5670 | 5704 |
| Tens. Str. at | MPa | 19.5 | 163 | 194 | 100 | 101 | 104 | 92.7 | 107 | 114 |
| Brk. | | | | | | | | | | |
| Roughness | μm | 0.017 | 0.029 | 0.556 | 0.04 | 0.135 | 0.1143 | 0.40 | 0.185 | 0.146 |
| MV | Pa · s | 53 | 230 | 320 | 170 | 158 | 194 | 109 | 216 | 225 |

Direct PVD

| | | | | |
|---|---|---|---|---|
| Adhesion | | 5B | 5B | 5B |
| after PVD | | | | |
| Vibration | min | <10 | <10 | >120 |
| Wear test | | | | |
| Salt spray | hr | >48 | >48 | >48 |
| test | | | | |
| Adhesion | | | | 5B |
| after PVD | | | | |
| Vibration | min | | | >120 |
| Wear test | | | | |
| Salt spray | hr | | | >48 |
| test | | | | |

| | Unit | E6 | E7 | E8 | E9 | E10 | E11 | E12 | E13 | E14 | E15 |
|---|---|---|---|---|---|---|---|---|---|---|---|
| Component | | | | | | | | | | | |
| PEI-Si | wt % | | | | | | | | | | |
| PEI-1 | wt % | | | | | | | | | | |
| PEI-2 | wt % | 81.8 | 70.8 | 75.8 | 75.8 | 65.8 | 47.8 | 70.8 | 74.8 | 70.8 | 74.8 |
| PPSU | wt % | | | | | | 30 | | | | |
| PPE | wt % | 0 | 4 | 4 | 4 | 4 | 4 | 4 | 0 | 4 | 0 |
| PEPQ | wt % | 0.1 | 0.1 | 0.1 | 0.1 | 0.1 | 0.1 | 0.1 | 0.1 | 0.1 | 0.1 |
| TBPP | wt % | 0.1 | 0.1 | 0.1 | 0.1 | 0.1 | 0.1 | 0.1 | 0.1 | 0.1 | 0.1 |
| Talc | wt % | 15 | | | 15 | | 15 | 15 | 15 | 15 | 15 |
| Clay | wt % | | 20 | | | 20 | | | | | |
| Wollastonite | wt % | | | 15 | | | | | | | |
| GF | wt % | | | | | | | | | | |
| PET | wt % | 3 | 5 | 5 | | | 3 | | | | |
| PBT | wt % | | | | 5 | | | | | | |
| LCP | wt % | | | | | | | | | | |
| PEEK | wt % | | | | | | | 10 | 10 | | |
| ITR-PC | wt % | | | | | 10 | | | | | |
| PPS | wt % | | | | | | | | | 10 | 10 |
| Properties | | | | | | | | | | | |
| HDT | ° C. | 176 | 168 | 169 | 160 | 175 | 180 | 183 | 190 | 187 | 191 |
| Flex. Mod. | MPa | 4810 | 5510 | 4530 | 5530 | 5090 | 4790 | 4960 | 5098 | 4810 | 4730 |
| Flex. Stress | MPa | 182 | 141 | 168 | 153 | 169 | 146 | 169 | 175 | 114 | 169 |
| Notched Izod | J/m | 33.1 | 35.5 | 35.9 | 31 | 34.1 | 33.1 | 31.2 | 45 | 35.0 | 34.1 |
| Impact | | | | | | | | | | | |
| Unnotched | J/m | 672 | 428 | 599 | 401 | 410 | 601 | 660 | 611 | 595 | 696 |
| Izod Impact | | | | | | | | | | | |
| Tens. Mod. | MPa | 5786 | 5360 | 4687 | 5863 | 5061 | 5257 | 5452 | 5322 | 5690 | 5610 |
| Tens. Str. at | MPa | 95 | 101 | 101 | 102 | 74 | 105 | 105 | 104 | 86 | 107 |
| Brk | | | | | | | | | | | |
| Roughness | μm | 0.159 | 0.065 | 0.122 | 0.119 | 0.066 | 0.112 | 0.132 | 0.147 | 0.098 | 0.093 |
| MV | Pa · s | 226 | 173 | 172 | 172 | 170 | 179 | 229 | 256 | 159 | 212 |

Direct PVD

| | | | | |
|---|---|---|---|---|
| Adhesion | | 5B | 5B | 5B |
| after PVD | | | | |
| Vibration | min | >120 | >120 | >120 |
| Wear test | | | | |
| Salt spray test | hr | >48 | >48 | >48 |

Electroless plating plus electroplating plus PVD

| | | | | |
|---|---|---|---|---|
| Adhesion | | 5B | 5B | 5B |
| after PVD | | | | |
| Vibration | min | >120 | >120 | >120 |
| Wear test | | | | |
| Salt spray test | hr | >48 | >48 | >48 |

As shown in Table 4, C1 is pure PEI-Si as a comparative example. C1 shows high surface gloss but lower heat resistance and lower modulus. There is some deflection after 120° C. PVD process and failure in vibration wear test after 10 minutes.

Comparative Examples C2 and C3 are PEI-2 blended with PPE as well as two filled examples (clay and glass fibers). As shown in Table 4, C2 showed high heat resistance, acceptable flowability, and high surface gloss and high heat resistance. However, PPO and PEI are immiscible, and the molded part was observed to exhibit peeling. To improve the miscibility, glass fibers (C3) were added and roughness of above 0.04 was observed. The flowability was also diminished. For C3, the modulus increased to above 5000 MPa and HDT increased to nearly 200° C., however the flowability decreased, and the surface exhibited glass fiber floating which is not desirable. Comparative Example C3 also failed in the vibration wear test after only 10 minutes. In Comparative Example C4, LCP was blended with PEI, PPE, and clay to investigate the influence of a flow promoter on the performance of the composition. The composition of C4 exhibited a good balance of flowability, high heat properties, high gloss, and high modulus, however the composition exhibited problems related peeling because PEI is immiscible with PPE and LCP.

To balance high modulus, high heat, high flowability, and high surface gloss, 3% and 5% of PET as a flow promoter and 15% of talc as a mineral filler were introduced in the composition of E1 and E2 comprising PEI-2 and PPE. From Table 4, it can be seen that the modulus increased above 5200 MPa, and the surface quality was good. Additionally, the melt viscosity at 5000 s⁻¹ was 158 and 194 Pa·s, respectively, indicating good flowability. The HDT decreased slightly relative to the comparative examples, however remained above 160° C. By increasing the loading of talc to 30% as in E3, the modulus increased to above 7900 MPa. To balance the flowability, the loading of PET increased, resulting in good flowability and retention of HDT above 160° C. Decreasing the PPE content to 2.5%, 1% and even 0% as in examples E4-E6, respectively, resulted in a slight decrease in flowability though still at an acceptable level.

In examples E7 and E8, the mineral clay and wollastonite was blended with PEI, PPE, and PET to investigate the influence of filler type on composition performance. Similar to talc, it was observed that clay and wollastonite could increase the modulus. The modulus for 20% loading of clay matched that of 15% loading of talc, and 15% loading of wollastonite exhibited a slight decrease in modulus compared to the composition with 15% loading of talc. The HDT of compositions including wollastonite and clay was lower, and the MV at 5000 s⁻¹ was slightly increased, compared to the compositions including talc.

Examples E9 and E10 include 5% PBT and 10% ITR-PC to further investigate the influence of flow promoter type on the performance of the composition. Similar to using PET as the flow promoter, the compositions exhibited a good balance of flowability, high heat performance, high surface gloss, and high modulus. With the same amount of mineral filler, the flowability of the composition with 10% ITR-PC was similar to that of the composition including 5% PET. The HDT of the composition with 10% ITR-PC was higher than the composition including 5% PET, while the modulus was observed to be slightly lower. The flowability of the composition with 5% PBT was improved relative to the composition including 5% PET, but the HDT of the composition with 5% PBT was lower.

In Example E11, 30% PPSU was used to replace a portion of the PEI. The resulting composition exhibited good flowability, high heat tolerance, and high modulus. PEEK (E12-E13) and PPS (E14-E15) were also used as a flow promoter, and the overall performance of the composition was good.

Accordingly, the compositions according to the present disclosure provide a solution to current requirements, particularly for molded parts suitable for use as metallized parts in consumer electronics. In particular, the compositions can provide high heat properties (HDT of greater than 150° C.), high stiffness (modulus of greater than 3000 MPa), good flowability (MV of less than 320 Pa·s at a shear rate of 5000 s⁻¹), and good surface properties (roughness of less than 0.4 μm).

This disclosure further encompasses the following aspects.

Aspect 1: An article comprising: a composition comprising 30 to 94 weight percent of a high heat amorphous thermoplastic polymer having a glass transition temperature of greater than 180° C.; 0 to 6 weight percent of a poly(phenylene ether) oligomer; 1 to 15 weight percent of a flow promoter comprising a polyester, a poly(carbonate-ester), an aromatic polyketone, poly(phenylene sulfide), or a combination thereof; and 1 to 40 weight percent of a mineral filler; wherein weight percent of each component is based on the total weight of the composition; and a metal layer disposed on a surface of the composition.

Aspect 2: The article of aspect 1, wherein the high heat amorphous thermoplastic polymer comprises a poly(etherimide), a poly(phenylsulfone), a poly(ethersulfone), a poly(sulfone), or a combination thereof.

Aspect 3: The article of aspect 1 or 2, wherein the high heat amorphous thermoplastic polymer comprises a poly(etherimide).

Aspect 4: The article of any of aspects 1 to 3, wherein the poly(phenylene ether) oligomer has an intrinsic viscosity of 0.03 to 0.2 deciliter per gram, preferably 0.08 to 0.15 deciliters per gram.

Aspect 5: The article of any of aspects 1 to 4, wherein the flow promoter comprises poly(ethylene terephthalate), poly(butylene terephthalate), an (isophthalate-terephthalate-resorcinol)-carbonate copolymer, poly(ether ether ketone), poly(phenylene sulfide), or a combination thereof.

Aspect 6: The article of any of aspects 1 to 5, wherein the flow promoter comprises a poly(ethylene terephthalate), a poly(ether ether ketone), a poly(phenylene sulfide), or a combination thereof, preferably a poly(ether ether ketone).

Aspect 7: The article of any of aspects 1 to 6, wherein the mineral filler comprises talc, kaolin clay, wollastonite, or a combination thereof, preferably talc.

Aspect 8: The article of any of aspects 1 to 7, wherein the mineral filler has an average particle size of less than 10 micrometers, or less than 2 micrometers.

Aspect 9: The article of any of aspects 1 to 8, wherein glass fibers are excluded from the composition.

Aspect 10: The article of any of aspects 1 to 9, wherein the composition further includes an additive, preferably wherein the additive is a thermal stabilizer, a mold release agent, a flame retardant, a colorant, or a combination thereof.

Aspect 11: The article of any of aspects 1 to 10, wherein the metal layer is deposited by electroless plating followed by electroplating followed by physical vapor deposition; or direct physical vapor deposition.

Aspect 12: The article of any of aspects 1 to 11, wherein the metal layer comprises Cr, Ni, Cu, Au, Ti, W, a titanium compound, a chromium compound, a tungsten compound, a silicone compound, or a combination thereof; preferably Cr, Ni, Cu, TiCr, TiN, TiC, TiSi, TiO, CrC, CrN, CrO, SiO, WC, WCr, WN, WO, or a combination thereof.

Aspect 13: The article of any of aspects 1 to 12, wherein the metal layer has a thickness of 1 to 100 micrometers, preferably 1 to 55 micrometers.

Aspect 14: The article of any of aspects 1 to 13, where the composition comprises: 50 to 94 weight percent, or 60 to 90 weight percent, or 65 to 85 weight percent of the high heat amorphous thermoplastic polymer, preferably wherein the high heat amorphous thermoplastic polymer is a poly(etherimide) or a combination of a poly(etherimide) and a poly(phenylsulfone); greater than 0 to 6 weight percent, or greater than 0 to 5 weight percent, or 1 to 5 weight percent, or 1 to 4 weight percent of a poly(phenylene ether) having an intrinsic viscosity of 0.03 to 0.2 deciliter per gram; 1 to 12 weight percent, or 3 to 12 weight percent of the flow promoter, preferably wherein the flow promoter is poly(ethylene terephthalate), poly(butylene terephthalate), an (isophthalate-terephthalate-resorcinol)-carbonate copolymer, poly(ether ether ketone), poly(phenylene sulfide), or a combination thereof, more preferably wherein the flow promoter is poly(ether ether ketone); and 3 to 30 weight percent, or 5 to 30 weight percent, or 5 to 20 weight percent of the mineral filler, preferably wherein the mineral filler comprises talc or kaolin clay, more preferably talc.

Aspect 15: The article of any of aspects 1 to 14, wherein the composition exhibits one or more of: a melt viscosity of less than 320 Pa·s at a temperature of 337° C. and a shear rate of 5000 s¹; a flexural modulus of greater than 3000 MPa; a heat deflection temperature of greater than 150° C.; and a surface roughness of less than 0.4 μm.

Aspect 16: The article of any of aspects 1 to 15, wherein the metal layer has a vibration resistance of at least ten minutes; a cross-hatch adhesion test classification of at least 4B; and a corrosion resistance of at least 48 hours as determined by a salt spray test according to ASTM B117.

Aspect 17: The article of any of aspects 1 to 16, wherein the article is a component of a consumer electronic device or an eyewear frame.

Aspect 18: A method of making the article of any of aspects 1 to 15, the method comprising: melt-mixing the components of the compositions; molding the composition; and depositing a metal layer on a surface of the molded composition by electroless plating, electroplating, physical vapor deposition, or a combination thereof.

Aspect 19: A composition comprising: 30 to 94 weight percent of a high heat amorphous thermoplastic polymer having a glass transition temperature of greater than 180° C.; 0 to 6 weight percent of a poly(phenylene ether); 1 to 15 weight percent of a flow promoter comprising a polyester, a poly(carbonate-ester), an aromatic polyketone, poly(phenylene sulfide), or a combination thereof; and 1 to 40 weight percent of a mineral filler; wherein weight percent of each component is based on the total weight of the composition.

Aspect 20: The composition of aspect 19, comprising: 50 to 94 weight percent, or 60 to 90 weight percent, or 65 to 85 weight percent of the high heat amorphous thermoplastic polymer, wherein the high heat amorphous thermoplastic polymer is a poly(etherimide) or a combination of a poly(etherimide) and a poly(phenylsulfone); greater than 0 to 6 weight percent, or greater than 0 to 5 weight percent of a poly(phenylene ether) having an intrinsic viscosity of 0.03 to 0.2 deciliter per gram; 1 to 12 weight percent, or 3 to 12 weight percent of the flow promoter, wherein the flow promoter is poly(ethylene terephthalate), poly(butylene terephthalate), an (isophthalate-terephthalate-resorcinol)-carbonate copolymer, poly(ether ether ketone), poly(phenylene sulfide), or a combination thereof, more preferably wherein the flow promoter is poly(ether ether ketone); and 3 to 30 weight percent, or 5 to 30 weight percent, or 5 to 20 weight percent, of the mineral filler, wherein the mineral filler comprises talc, kaolin clay, wollastonite, or a combination thereof; and wherein the composition exhibits one or more of: a melt viscosity of less than 320 Pa·s at a temperature of 337° C. and a shear rate of 5000 s¹; a flexural modulus of greater than 3000 MPa; a heat deflection temperature of greater than 150° C.; and a surface roughness of less than 0.4 μm.

The compositions, methods, and articles can alternatively comprise, consist of, or consist essentially of, any appropriate materials, steps, or components herein disclosed. The compositions, methods, and articles can additionally, or alternatively, be formulated so as to be devoid, or substantially free, of any materials (or species), steps, or components, that are otherwise not necessary to the achievement of the function or objectives of the compositions, methods, and articles.

All ranges disclosed herein are inclusive of the endpoints, and the endpoints are independently combinable with each other. “Combinations” is inclusive of blends, mixtures, alloys, reaction products, and the like. The terms “first,” “second,” and the like, do not denote any order, quantity, or importance, but rather are used to distinguish one element from another. The terms “a” and “an” and “the” do not denote a limitation of quantity, and are to be construed to cover both the singular and the plural, unless otherwise indicated herein or clearly contradicted by context. “Or” means “and/or” unless clearly stated otherwise. Reference throughout the specification to “some aspects,” “an aspect,” and so forth, means that a particular element described in connection with the aspect is included in at least one aspect described herein, and may or may not be present in other aspects. The term “combination thereof” as used herein includes one or more of the listed elements, and is open, allowing the presence of one or more like elements not named. In addition, it is to be understood that the described elements may be combined in any suitable manner in the various aspects.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this application belongs. All cited patents, patent applications, and other references are incorporated herein by reference in their entirety. However, if a term in the present application contradicts or conflicts with a term in the incorporated reference, the term from the present application takes precedence over the conflicting term from the incorporated reference.

Compounds are described using standard nomenclature. For example, any position not substituted by any indicated group is understood to have its valency filled by a bond as indicated, or a hydrogen atom. A dash (“-”) that is not between two letters or symbols is used to indicate a point of attachment for a substituent. For example, —CHO is attached through carbon of the carbonyl group.

As used herein, the term “hydrocarbyl”, whether used by itself, or as a prefix, suffix, or fragment of another term, refers to a residue that contains only carbon and hydrogen. The residue can be aliphatic or aromatic, straight-chain, cyclic, bicyclic, branched, saturated, or unsaturated. It can also contain combinations of aliphatic, aromatic, straight chain, cyclic, bicyclic, branched, saturated, and unsaturated hydrocarbon moieties. However, when the hydrocarbyl residue is described as substituted, it can, optionally, contain heteroatoms over and above the carbon and hydrogen members of the substituent residue. Thus, when specifically described as substituted, the hydrocarbyl residue can also contain one or more carbonyl groups, amino groups, hydroxyl groups, or the like, or it can contain heteroatoms within the backbone of the hydrocarbyl residue. The term “alkyl” means a branched or straight chain, saturated aliphatic hydrocarbon group, e.g., methyl, ethyl, n-propyl, i-propyl, n-butyl, s-butyl, t-butyl, n-pentyl, s-pentyl, and n- and s-hexyl. “Alkenyl” means a straight or branched chain, monovalent hydrocarbon group having at least one carbon-carbon double bond (e.g., ethenyl (—HC═CH₂)). “Alkoxy” means an alkyl group that is linked via an oxygen (i.e., alkyl-O—), for example methoxy, ethoxy, and sec-butyloxy groups. “Alkylene” means a straight or branched chain, saturated, divalent aliphatic hydrocarbon group (e.g., methylene (—CH₂—) or, propylene (—(CH₂)₃—)). “Cycloalkylene” means a divalent cyclic alkylene group, —CₙH₂ₙ₋ₓ, wherein x is the number of hydrogens replaced by cyclization(s). “Cycloalkenyl” means a monovalent group having one or more rings and one or more carbon-carbon double bonds in the ring, wherein all ring members are carbon (e.g., cyclopentyl and cyclohexyl). “Aryl” means an aromatic hydrocarbon group containing the specified number of carbon atoms, such as phenyl, tropone, indanyl, or naphthyl. “Arylene” means a divalent aryl group. “Alkylarylene” means an arylene group substituted with an alkyl group. “Arylalkylene” means an alkylene group substituted with an aryl group (e.g., benzyl). The prefix “halo” means a group or compound including one more of a fluoro, chloro, bromo, or iodo substituent. A combination of different halo groups (e.g., bromo and fluoro), or only chloro groups can be present. The prefix “hetero” means that the compound or group includes at least one ring member that is a heteroatom (e.g., 1, 2, or 3 heteroatom(s)), wherein the heteroatom(s) is each independently N, O, S, Si, or P. “Substituted” means that the compound or group is substituted with at least one (e.g., 1, 2, 3, or 4) substituents that can each independently be a C₁₋₉ alkoxy, a C₁₋₉ haloalkoxy, a nitro (—NO₂), a cyano (—CN), a C₁₋₆ alkyl sulfonyl (—S(═O)₂-alkyl), a C₆₋₁₂ aryl sulfonyl (—S(═O)₂-aryl), a thiol (—SH), a thiocyano (—SCN), a tosyl (CH₃C₆H₄SO₂—), a C₃₋₁₂ cycloalkyl, a C₂₋₁₂ alkenyl, a C₅₋₁₂ cycloalkenyl, a C₆₋₁₂ aryl, a C₇₋₁₃ arylalkylene, a C₄₋₁₂ heterocycloalkyl, and a C₃₋₁₂ heteroaryl instead of hydrogen, provided that the substituted atom's normal valence is not exceeded. The number of carbon atoms indicated in a group is exclusive of any substituents. For example —CH₂CH₂CN is a C₂ alkyl group substituted with a nitrile.

While particular aspects have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

1. An article comprising:
a composition comprising
30 to 94 weight percent of a high heat amorphous thermoplastic polymer having a glass transition temperature of greater than 180° C.;
0 to 6 weight percent of a poly(phenylene ether) oligomer;
1 to 15 weight percent of a flow promoter comprising a polyester, a poly(carbonate-ester), an aromatic polyketone, poly(phenylene sulfide), or a combination thereof; and
1 to 40 weight percent of a mineral filler;
wherein weight percent of each component is based on the total weight of the composition; and
a metal layer disposed on a surface of the composition.

2. The article of claim 1, wherein the high heat amorphous thermoplastic polymer comprises a poly(etherimide), a poly(phenylsulfone), a poly(ethersulfone), a poly(sulfone), or a combination thereof.

3. The article of claim 1, wherein the high heat amorphous thermoplastic polymer comprises a poly(etherimide).

4. The article of claim 1, wherein the poly(phenylene ether) oligomer has an intrinsic viscosity of 0.03 to 0.2 deciliter per gram.

5. The article of claim 1, wherein the flow promoter comprises poly(ethylene terephthalate), poly(butylene terephthalate), an (isophthalate-terephthalate-resorcinol)-carbonate copolymer, poly(ether ether ketone), poly(phenylene sulfide), or a combination thereof.

6. The article of claim 1, wherein the flow promoter comprises a poly(ethylene terephthalate), a poly(ether ether ketone), a poly(phenylene sulfide), or a combination thereof.

7. The article of claim 1, wherein the mineral filler comprises talc, kaolin clay, wollastonite, or a combination thereof.

8. The article of claim 1, wherein the mineral filler has an average particle size of less than 10 micrometers.

9. The article of claim 1, wherein glass fibers are excluded from the composition.

10. The article of claim 1, wherein the composition further includes an additive.

11. The article of claim 1, wherein the metal layer is deposited by
electroless plating followed by electroplating followed by physical vapor deposition; or
direct physical vapor deposition.

12. The article of claim 1, wherein the metal layer comprises Cr, Ni, Cu, Au, Ti, W, a titanium compound, a chromium compound, a tungsten compound, a silicone compound, or a combination thereof.

13. The article of claim 1, wherein the metal layer has a thickness of 1 to 100 micrometers.

14. The article of claim 1, where the composition comprises:
50 to 94 weight percent of the high heat amorphous thermoplastic polymer;
greater than 0 to 6 weight percent a poly(phenylene ether) having an intrinsic viscosity of 0.03 to 0.2 deciliter per gram;
1 to 12 weight percent of the flow promoter; and
3 to 30 weight percent of the mineral filler.

15. The article of claim 1, wherein the composition exhibits one or more of:
a melt viscosity of less than 320 Pa·s at a temperature of 337° C. and a shear rate of 5000 s¹;
a flexural modulus of greater than 3000 MPa;
a heat deflection temperature of greater than 150° C.; and
a surface roughness of less than 0.4 μm.

16. The article of claim 1, wherein the metal layer has
a vibration resistance of at least ten minutes;
a cross-hatch adhesion test classification of at least 4B; and
a corrosion resistance of at least 48 hours as determined by a salt spray test according to ASTM B117.

17. The article of claim 1, wherein the article is a component of a consumer electronic device or an eyewear frame.

18. A method of making the article of claim 1, the method comprising:
melt-mixing the components of the compositions;
molding the composition; and
depositing a metal layer on a surface of the molded composition by electroless plating, electroplating, physical vapor deposition, or a combination thereof.

19. A composition comprising:
30 to 94 weight percent of a high heat amorphous thermoplastic polymer having a glass transition temperature of greater than 180° C.;
0 to 6 weight percent of a poly(phenylene ether);
1 to 15 weight percent of a flow promoter comprising a polyester, a poly(carbonate-ester), an aromatic polyketone, poly(phenylene sulfide), or a combination thereof; and
1 to 40 weight percent of a mineral filler;
wherein weight percent of each component is based on the total weight of the composition.

20. The composition of claim 19, comprising:
50 to 94 weight percent, of the high heat amorphous thermoplastic polymer, wherein the high heat amorphous thermoplastic polymer is a poly(etherimide) or a combination of a poly(etherimide) and a poly(phenylsulfone);
greater than 0 to 6 weight percent of a poly(phenylene ether) having an intrinsic viscosity of 0.03 to 0.2 deciliter per gram;
1 to 12 weight percent of the flow promoter, wherein the flow promoter is poly(ethylene terephthalate), poly(butylene terephthalate), an (isophthalate-terephthalate-resorcinol)-carbonate copolymer, poly(ether ether ketone), poly(phenylene sulfide), or a combination thereof, more preferably wherein the flow promoter is poly(ether ether ketone); and
3 to 30 weight percent of the mineral filler, wherein the mineral filler comprises talc, kaolin clay, wollastonite, or a combination thereof;
and wherein the composition exhibits one or more of:
a melt viscosity of less than 320 Pa·s at a temperature of 337° C. and a shear rate of 5000 s¹;
a flexural modulus of greater than 3000 MPa;
a heat deflection temperature of greater than 150° C.; and
a surface roughness of less than 0.4 μm.
